(19) United States
(12) Patent Application Publication
(10) Pub. No.: US 2006/0096532 A1
(43) Pub. Date: May 11, 2006

(54) Thin film forming apparatus

(76) Inventor: Joo-Sik Yoon, Gyungsangbuk (KR)

Correspondence Address: DILWORTH & BARRESE, LLP, 333 EARLE OVINGTON BLVD., UNIONDALE, NY, 11553, US

(21) Appl. No.: 10/533,828

(22) PCT Filed: Dec. 14, 2002
(86) PCT No.: PCT/KR02/02361

§ 371 Date: May 3, 2005

(51) Int. Cl. C23C 16/00

(52) U.S. Cl. 118/715

(57) ABSTRACT

The present invention relates to a thin forming apparatus, i.e. an apparatus for forming thin films of various materials on substrates, for example, in processes of fabricating semiconductor wafers or liquid crystal displays (LCDs). The thin film forming apparatus comprises a substrate support for mounting a substrate on which a thin film is to be formed, and a chamber that encloses the substrate support and has proper operation conditions. Then, adsorption means constructed by applying a ductile metal material such as indium, tin, lead or antimony on a metal or synthetic resin base material are attached to surfaces of components within the thin film forming apparatus except the substrate. Accordingly, it is possible to fundamentally prevent failure of formation of a thin film due to adhesion of a portion of an unnecessary thin film, which has been formed on and then peeled off from the surfaces of the components, to the substrate.

### TECHNICAL FIELD

The present invention relates to a thin film forming apparatus, i.e. an apparatus for forming thin films of various materials on substrates, for example, in processes of fabricating semiconductor wafers or liquid crystal displays (LCDs). More particularly, the present invention relates to a thin film forming apparatus capable of fundamentally preventing failure of formation of a thin film due to adhesion of a portion of a thin film, which has been formed on and then peeled off from surfaces of components within the apparatus except the substrate, to the substrate.

Thin film forming apparatuses used herein mean substantially all kinds of thin film forming apparatuses including thin film forming apparatuses employing physical vapor deposition (PVD) techniques such as vapor deposition, molecular beam epitaxy, laser ablation, sputter deposition, ion plating, ionized cluster beam deposition and ion beam deposition, and thin film forming apparatuses employing chemical vapor deposition (CVD) techniques such as thermal vapor deposition, photo CVD and plasma CVD.

### BACKGROUND ART

As in cases of the aforementioned semiconductor wafers or LCDs, electric appliances with thin films of particular materials formed on substrates have been widely popularized in relevant fields of industries.

Of course, since the usefulness and importance of such electric appliances have increased, a variety of techniques and relevant apparatuses for forming superior thin films on substrates have been developed.

Such a thin film forming apparatus generally comprises a substrate support for mounting a substrate on which a thin film is to be formed, and a chamber that encloses the substrate support and has proper operation conditions.

That is, the thin film forming apparatus is to form a thin film by depositing particles of a specific material on a substrate within the chamber by means of a physical or chemical method

Some of such thin film forming apparatuses employing PVD or CVD techniques will be described below by way of examples.

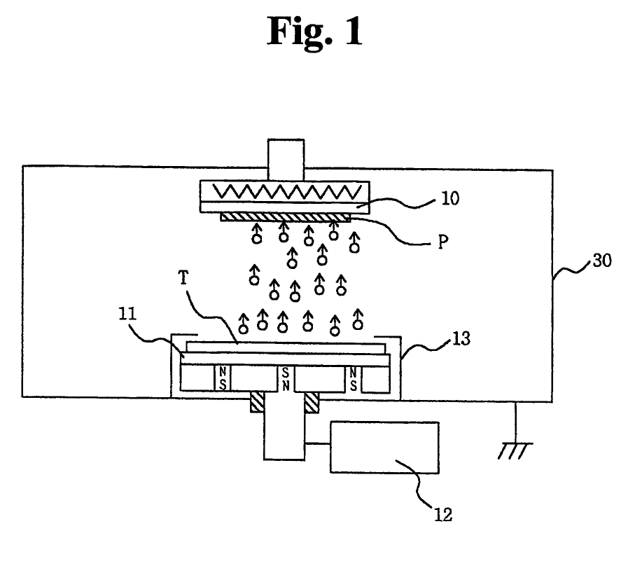

FIG. 1 shows a high frequency magnetron sputter apparatus employing sputter deposition that is one of PVD techniques.

As described above, this apparatus comprises a substrate support 10 for mounting a substrate P on which a thin film is to be formed, and a chamber 30 that encloses the substrate support 10 and has proper operation conditions.

A target T is put on a backing plate 11 installed opposite to the substrate support 10, and a high voltage is then applied to the target by operating a high frequency power supply 12. Accordingly, a large number of particles of the material of the target, i.e. ions, are produced from the surface of the target T by means of a sputtering phenomenon and move toward the substrate P to form a thin film on the surface of the substrate P.

Reference numeral 13 designates a shield that is in charge of grounding the target T and the backing plate 11 and simultaneously assists in causing the target material particles to have proper directionality.

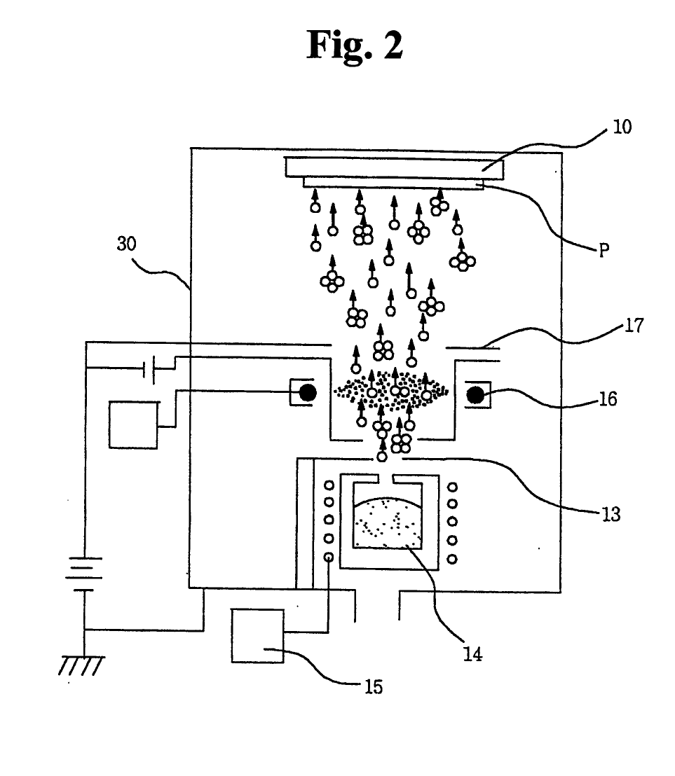

FIG. 2 shows a thin film forming apparatus employing ionized cluster beam deposition that is one of PVD techniques.

Similarly to the aforementioned sputter apparatus, this apparatus also comprises a substrate support 10 for mounting a substrate P, and a chamber 30 that encloses the substrate support 10 and has proper operation conditions.

A target material is put in an electric furnace 14 opposite to the substrate support 10, and a high voltage is then applied to the electric furnace 14 by operating a filament power supply 15. Accordingly, a large number of ions are ejected from the target material and move toward the substrate P to form a thin film on the surface of the substrate P.

Meanwhile, these ions are in the form of a cluster while passing through an additional filament 16 and an accelerating electrode 17.

Reference numeral 13 designates a shield performing the same function as that of the apparatus shown in FIG. 1. Even in the following descriptions of other apparatuses, like reference numerals designate like elements performing the same functions.

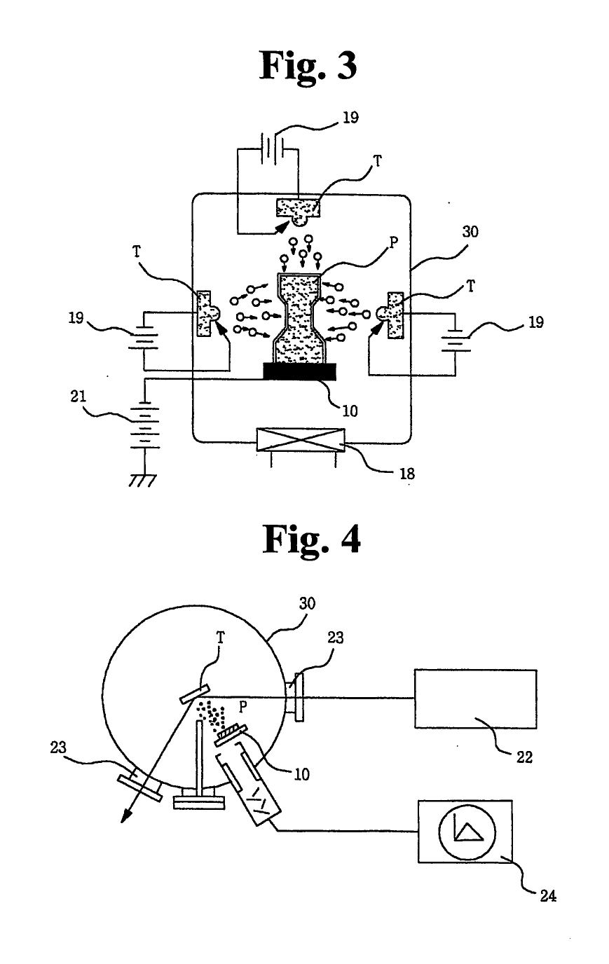

FIG. 3 shows a multi-arc discharging apparatus employing ion plating that is one of PVD techniques.

In this case, a substrate P on which a thin film is to be formed is put on a substrate support 10 installed at the center of a chamber 30, and a high voltage is applied to targets T disposed above and beside the substrate P. Accordingly, a large number of ions are produced from the surface of each of the targets T and move toward the substrate P to form a thin film on the surface of the substrate P.

Reference numeral 18 designates an evacuation duct for achieving a proper level of vacuum within the chamber 30. Although not shown in the figure, such an evacuation duct 18 is also provided in the previous apparatuses.

Meanwhile, reference numeral 19 designates an arc power supply that serves to generate an arc on the target T to produce particles therefrom.

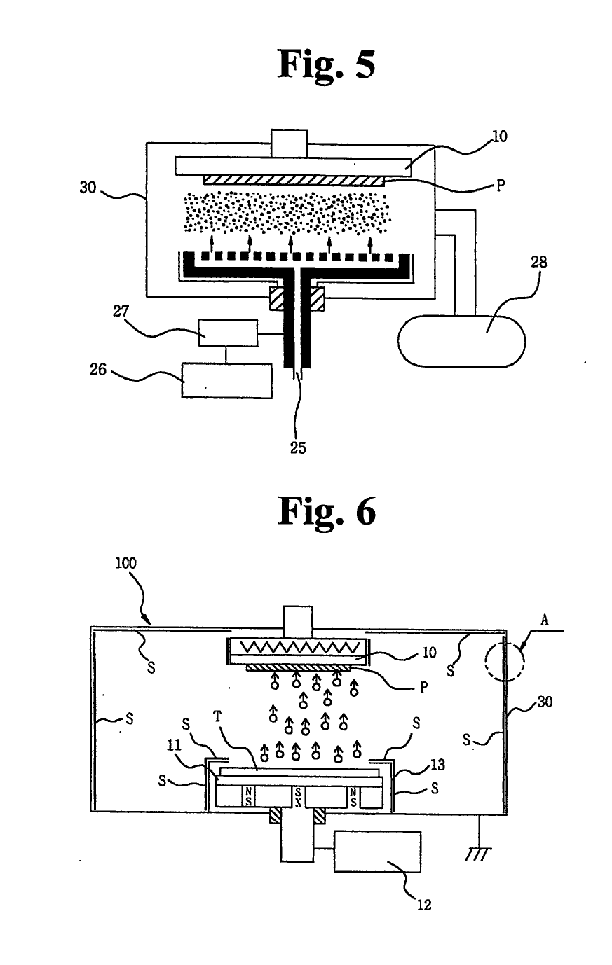

FIG. 4 shows a thin film forming apparatus employing laser ablation that is one of PVD techniques.

As shown in the figure, a laser beam is projected on a target T placed on a target support 11 at the center of a cylindrical chamber 30. Then, gaseous particles are ejected in the form of a column from the surface of the target T and move toward the substrate P opposite to the target T to form a thin film on the substrate P.

Reference numeral 22 designates a laser generator for generating a laser beam, and reference numeral 24 designates a viewing window for allowing an operator to view the status of operations within the chamber 30.

The status of formation of a thin film on the substrate P is monitored through an additional electronic monitor 24 provided outside the chamber 30.

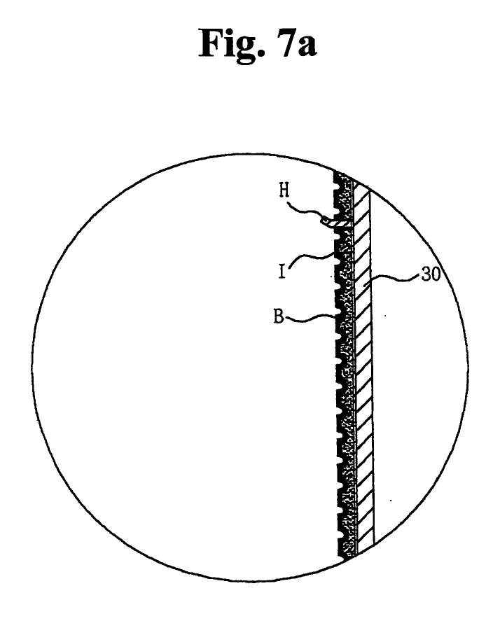

Meanwhile, FIG. 5 shows a thin film forming apparatus employing plasma CVD that is one of CVD techniques.

Similarly to the aforementioned apparatuses employing PVD techniques, this apparatus also comprises a substrate support 10 for mounting a substrate P, and a chamber 30 that encloses the substrate support 10 and the substrate and has proper operation conditions.

In the thin film forming apparatus employing CVD, source gases are injected into the chamber through a gas injection port 25. Then, the source gases become plasma, i.e. charged particle state, while passing through a passage connected to a high frequency power supply 26 and a matching box 27. The charged particles move toward the substrate P within the chamber 30 to form a thin film on the substrate P.

In case of the plasma CVD apparatus, the gases injected through the gas injection port 25 circulate within the chamber 30 and are involved in the formation of the thin film and then discharged toward an exhaust gas processing device 28, thereby establishing one cycle.

Conventional thin film forming apparatuses employing PVD or CVD techniques have performed the original function of forming thin films of various materials on substrates. However, these apparatuses have not yet fundamentally solved problems due to adhesion of particulate or gaseous target materials on surfaces of components within the apparatuses except substrates.

In other words, some of target material particles adhere other portions except a substrate rather than accurately moving toward the substrate and thus forming a predetermined thin film on the substrate. As a result, an unnecessary thin film is formed. In some instances, the thickness of the thin film may gradually increase with time and a portion of the thin film may be peeled off due to physical, electrical or chemical impact and the like during an operation.

A portion of the thin film is peeled off in the form of particles or agglomerates. Some of the peeled particles or agglomerates move toward and adhere on the substrate on which a thin film is being formed. This causes critical failure of formation of the thin film.

To solve this problem, there have been proposed various solutions including improvement of adhesiveness of target material particles by roughening surfaces of components, such as chambers or shields, within thin film forming apparatuses. However, these solutions have not exhibited any effects over a slight delay of peeling of a portion of a thin film.

### DISCLOSURE OF INVENTION

The present invention is conceived to solve the problems in the prior art. An object of the present invention is to provide a thin film forming apparatus capable of fundamentally preventing failure of formation of a thin film due to adhesion of a portion of a thin film, which has been formed on and then peeled off from surfaces of components within the apparatus except a substrate, to the substrate.

According to the present invention for achieving the object, there is provided a thin film forming apparatus including a substrate support for mounting a substrate on which a thin film is to be formed, and a chamber which encloses the substrate support and has proper operation conditions, comprising adsorption means attached to surfaces of components within the thin film forming apparatus except the substrate.

That is, the adsorption means with high adsorption capability are attached to portions of the thin film forming apparatus except the substrate, i.e. the chamber, a shield and the like. Accordingly, particles of a target material which have adhered to the adsorption means to form thin films never be peeled off therefrom.

Each of the adsorption means is constructed by applying a solder metal material with hot adhesiveness and ductility such as indium (In), tin (Sn), lead (Pb), antimony (Sb) or silver (Ag) to the surface of a metal or synthetic resin base material.

In a preferred embodiment, the solder metal material such as indium is a ductile metal with ductility to the extent that it can be marked with a fingernail at room temperature. In addition to the ductility, the solder metal material further has adhesiveness at a proper high temperature within the chamber during a thin film forming process, thereby serving to securely prevent the target material particles, which have adhered to the portions of the apparatus except the substrate, from being peeled off therefrom.

### BEST MODE FOR CARRYING OUT THE INVENTION

Hereinafter, a thin film forming apparatus according to a preferred embodiment of the present invention will be described in detail with reference to the accompanying drawings.

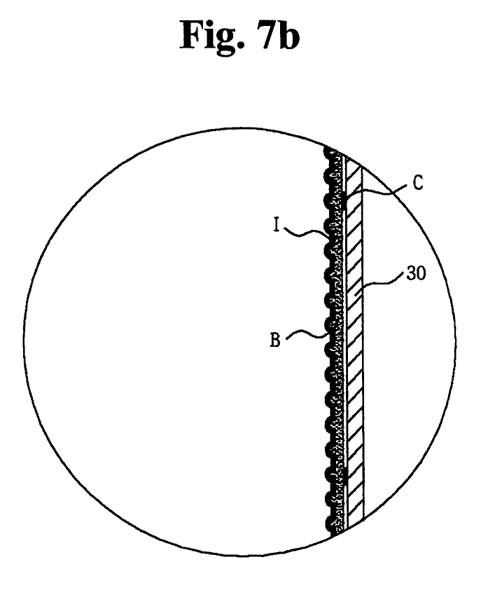

FIG. 6 shows a thin film forming apparatus according to an embodiment of the present invention, wherein adsorption means S are attached to surfaces of major components constituting a high frequency magnetron sputter apparatus.

As shown in the figure, most of a large number of particles ejected from the surface of a target T by means of a sputtering phenomenon move toward a substrate P to form a thin film of a proper thickness on the surface of the substrate. However, some of the particles move toward the components within the apparatus such as inner walls of a chamber 30 or a shield 13.

Since the adsorption means S with strong adhesiveness are attached to the surfaces of the components, the particles moving toward the inner walls of the chamber 30 or the like are very strongly adsorbed by an applied solder metal material I such as indium (In) on the surfaces of the adsorption means S and thus are hardly peeled off therefrom, contrary to a conventional thin film forming apparatus in which they adhere on the surfaces of the components and thus form a single peelable thin film.

As described above, each of the adsorption means S is obtained by melting a solder metal material such as indium (In) and applying the molten solder metal material to a metal or synthetic resin base material B.

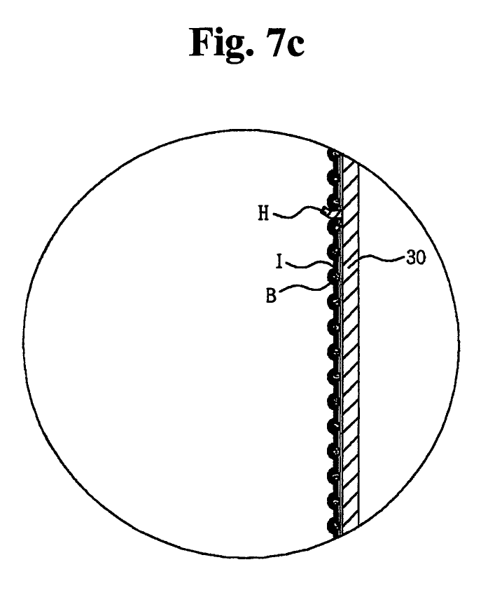

The base material B has some flexibility for easy handling thereof. As shown in FIGS. 7a and 7b, it is preferred that a plurality of grooves or protrusions be formed on the surface of the base material to more facilitate the adhesion of the particles thereto.

These grooves or protrusions may take any shapes including circular, polygonal and linear shapes.

Further, FIG. 7c shows a case where the base material B has a net-like structure that is constructed by selecting a net body with proper dimensions of wire diameter and mesh and applying a solder metal material such as indium (In) to a side surface thereof.

As for a method of applying the solder metal material such as indium (In) to the base material B, a variety of methods such as thermal spraying or brush application may be employed. In the present embodiment, the applying method itself does not have a significant meaning.

As for a method of attaching the adsorption means S to the inner walls of the chamber 30 or the like, there is a method of attaching the adsorption means S to the surfaces of the components such as the chamber 30 by using hooks H additionally formed on the surfaces of the components, as shown in FIG. 7a Alternatively, as shown in FIG. 7b, a back surface of the base material B may be welded (at a welded portion C) to the surface of each of the components such as the chamber 30.

Meanwhile, it is most preferred that indium (In) be used as a hot adhesive and ductile material applied to the surface of the base material. However, depending on temperature conditions within the chamber, other ductile metal materials such as tin (Sn) or lead (Pb) may be selected.

Those skilled in the art can change or modify the substance, grooves or shape of the base material, or select other methods of attaching the base material in view of the above description. Thus, it should be understood that various modifications and changes fall within the scope of the present invention so far as the adsorption means to which a ductile metal material such as indium has been applied are attached to surfaces of components within a thin film forming apparatus except a substrate.

### INDUSTRIAL APPLICABILITY

According to the thin film forming apparatus of the present invention described above, the adsorption means each of which comprises the base material and the solder metal material such as indium are attached to the surfaces of the components within the thin film forming apparatus except the substrate. Accordingly, it is possible to fundamentally prevent failure of formation of a thin film due to adhesion of a portion of a thin film, which has been formed on and then peeled off from the surfaces of the components within the apparatus except the substrate, to the substrate.

The thin film forming apparatus of the present invention is very useful in the relevant fields of industries under the current situation where productivity is greatly lowered due to failure of formation of thin films during processes of fabricating high-technology electronic devices such as semiconductor wafers or LCDs.

1. A thin forming apparatus including a substrate support for mounting a substrate on which a thin film is to be formed, and a chamber which encloses the substrate support and has proper operation conditions, comprising:
adsorption means attached to surfaces of components within the thin film forming apparatus except the substrate.

2. The apparatus as claimed in claim 1, wherein each of the adsorption means is constructed by applying a solder metal material on a surface of a metal base material.

3. The apparatus as claimed in claim 1, wherein each of the adsorption means is constructed by applying solder metal material on a surface of a synthetic resin base material.

4. The apparatus as claimed in claim 2, wherein a plurality of grooves are formed on the surface of the based material.

5. The apparatus as claimed in claim 2, wherein a plurality of protrusions are formed on the surface of the base material.

6. The apparatus as claimed in claim 2, wherein the base material is in the form of a net.

7. The apparatus as claimed in claim 3, wherein a plurality of grooves are formed on the surface of the based material.

8. The apparatus as claimed in claim 3, wherein a plurality of protrusions are formed on the surface of the base material.

9. The apparatus as claimed in claim 3, wherein the base material is in the form of a net.
